(19) United States
(12) Patent Application Publication
(10) Pub. No.: US 2019/0035661 A1
(43) Pub. Date: Jan. 31, 2019

(54) CONVEYANCE DEVICE AND WASHING DEVICE

(71) Applicant: Sakai Display Products Corporation, Osaka (JP)

(72) Inventor: Tomochika NAKATANI, Sakai-shi (JP)

(73) Assignee: Sakai Display Products Corporation, Osaka (JP)

(21) Appl. No.: 16/073,538

(22) PCT Filed: Jan. 29, 2016
(86) PCT No.: PCT/JP2016/052757

§ 371 Date: Jul. 27, 2018

(51) Int. Cl. H01L 21/677; B08B 3/04; H01L 21/67; B65G 39/10

(52) U.S. Cl. CPC H01L 21/67706; B65G 39/10; H01L 21/67051; B08B 3/041

(57) ABSTRACT

Provided are a conveyance device and a washing device that, when washing a glass substrate while conveying the same at a slant, can steadily convey the glass substrate. A conveyance device according to the present invention comprises a first frame, a second frame that is provided in a higher location that the first frame and is substantially parallel to the first frame, and a plurality of conveyance rollers that are axle-suspended between the first frame and the second frame, said conveyance rollers each having a surface that is formed from an elastic body and having a diameter expansion section on one end side, said end side being on the first frame side, in which diameter expansion section the diameter of the roller gradually expands toward said one end.

### TECHNICAL FIELD

The present invention relates to a conveyance device and a washing device that are capable of preventing a glass substrate from breaking when the glass substrate being tilted is conveyed and washed.

### BACKGROUND ART

A glass substrate that is used in a liquid crystal display apparatus is washed using a washing device in a production process of the liquid crystal display apparatus in order to, for example, clean surfaces of the glass substrate before film formation thereon.

An example of known washing devices for glass substrates washes a glass substrate by spraying cleaning water onto the glass substrate from above while conveying the glass substrate using a plurality of conveyance rollers with conveyance rolls attached thereto.

Another example of known washing devices for glass substrates includes inclined conveyance rollers in order to prevent cleaning water from remaining on a glass substrate or save cleaning water. That is, this washing device tilts a glass substrate and washes the glass substrate while conveying the tilted glass substrate (see Patent Literature, for example). A lower end of each of the conveyance rollers of the washing device disclosed in Patent Literature 1 has a collar portion having a larger diameter than the other portions of the conveyance roller in order to prevent the glass substrate from sliding down.

### CITATION LIST

### Patent Literature

[Patent Literature 1]

Japanese Patent Application Laid-Open Publication No. 2004-95926

### SUMMARY OF INVENTION

### Technical Problem

According to the above-described configuration, however, the collar portions at the lower ends of the conveyance rollers may damage a lower end of the glass substrate due to friction therewith. In a situation in which the collar portions of any adjacent conveyance rollers become misaligned in terms of height, a corner of the glass substrate may come down into a space between the collar portions of the adjacent conveyance rollers and get caught in rotation of the conveyance rollers to result in a glass break.

The present invention has been made in view of the circumstances described above, and an object thereof is to provide a conveyance device and a washing device that are capable of preventing glass substrates from breaking while being conveyed.

### Solution to Problem

A conveyance device according to an embodiment of the present disclosure includes a first frame, a second frame, and a plurality of conveyance rollers. The second frame is disposed at a higher location than the first frame and arranged substantially parallel to the first frame. The conveyance rollers are axially supported on the first frame and the second frame. The conveyance rollers each have a surface formed from an elastic material and an enlarged portion at one end thereof toward the first frame. The enlarged portion has a diameter gradually increasing toward the one end.

A washing device according to an embodiment of the present disclosure includes the above-described conveyance device and a spray section. The spray section is disposed above the conveyance device and sprays cleaning water downward.

### Advantageous Effects of Invention

According to embodiments of the present disclosure, a conveyance device and a washing device are provided that are capable of stably conveying a glass substrate being tilted while preventing the glass substrate from breaking when the glass substrate being tilted is conveyed and washed.

### BRIEF DESCRIPTION OF DRAWINGS

FIG. 1 is a perspective view schematically illustrating a washing device according to Embodiment 1.

FIG. 2 is a longitudinal cross-sectional view schematically illustrating the washing device according to Embodiment 1.

FIG. 3 is a perspective view schematically illustrating a washing device according to Embodiment 2.

FIG. 4 is a longitudinal cross-sectional view schematically illustrating the washing device according to Embodiment 2.

### DESCRIPTION OF EMBODIMENTS

The following describes embodiments of the present invention in detail based on the drawings. It is to be understood that the embodiments described below are merely examples and the present invention is not limited to configurations described below.

### Embodiment 1

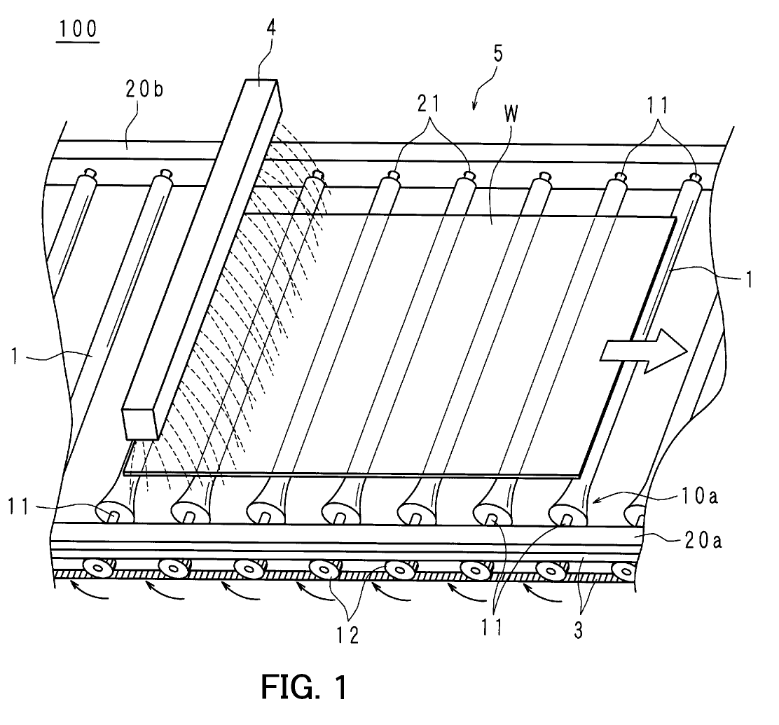

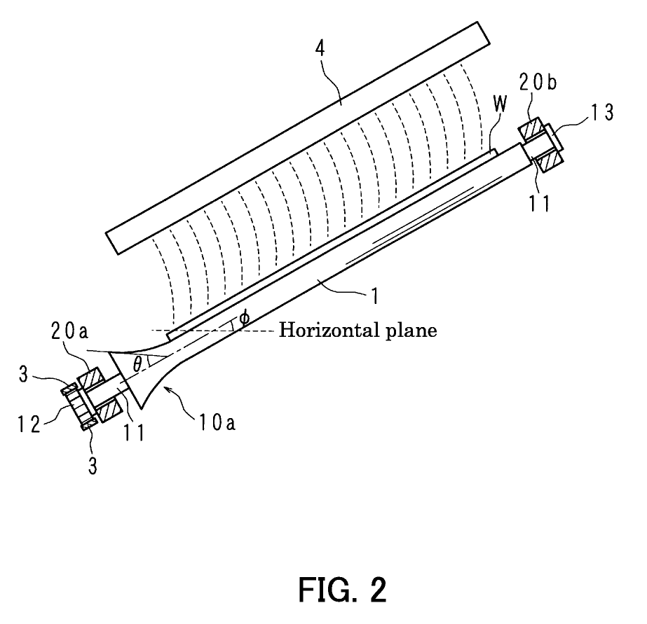

FIG. 1 is a perspective view schematically illustrating a washing device 100 according to Embodiment 1. FIG. 2 is a longitudinal cross-sectional view schematically illustrating the washing device 100. The washing device 100 includes a conveyance device 5 and a spray section 4. The conveyance device 5 includes conveyance rollers 1, pulleys 12, two frames 20 (a first frame 20a and a second frame 20b), and a timing belt 3. The conveyance device 5 conveys a work W (for example, a glass substrate). The washing device 100 sprays cleaning water onto the work W being conveyed by the conveyance device 5 to wash the work W.

The two frames 20 are arranged substantially parallel to each other at different heights. Specifically, the second frame 20b is disposed at a higher location than the first frame 20a and arranged substantially parallel to the first frame 2a. The conveyance rollers 1 are axially supported on the first frame 20a and the second frame 20b through roller shafts 11.

Both ends of each roller shaft 11 protrude outward from the frames 20 at the respective ends through shaft holes 21 respectively formed in the frames 20. The end protruding from the second frame 20b has a stopper 13 for restricting movement of the roller shaft 11 in an axial direction. The end of the roller shaft 11 protruding from the first frame 20a has one of the pulleys 12, which are each a driven pulley with teeth.

At least a surface (an outer circumferential surface) of each conveyance roller 1 is formed from an elastic material such as a resin that for example provides grip. Each conveyance roller 1 according to the present embodiment has the roller shaft 11 as a rotating shaft thereof. Other than the roller shaft 11, the conveyance roller 1 is formed from an elastic material such as silicone rubber. Each conveyance roller 1 has an enlarged portion 10a at one end thereof, which in other words is a lower end, toward the first frame 20a, and the enlarged portion 10a has a diameter gradually increasing toward the one end. An outer circumferential surface of the enlarged portion 10a is a curved surface such that, for example, the outline of a longitudinal cross-section of the enlarged portion 10a is a curved line.

Accordingly, each conveyance roller 1 is inclined relative to a horizontal plane as illustrated in FIG. 2 and is axially supported such that one of tangent lines to the curved line in a longitudinal cross-section of the conveyance roller 1 is substantially parallel to the horizontal plane represented by a dashed line. Specifically, an inclination angle Φ of each conveyance roller 1 relative to the horizontal plane is smaller than or equal to a largest inclination angle θ in the enlarged portion 10a of the conveyance roller 1 relative to the axial direction (dashed-dotted line). For example, the largest inclination angle in the enlarged portion 10a of each conveyance roller 1 relative to the axial direction is 45°, and the inclination angle Φ of the conveyance roller 1 is 30°.

The above-described conveyance rollers 1 are axially supported on the first frame 20a and the second frame 20b and arranged at specific intervals. The timing belt 3 is stretched around the pulleys 12 that are located outside of the first frame 20a and that are arranged in a longitudinal direction of the first frame 20a. The timing belt 3 is driven by a motor, not shown, to rotate in a specific direction. The driven pulleys 12 rotate with rotation of the timing belt 3 driven by the motor, causing the conveyance rollers 1 to rotate in the same direction and at the same speed.

The spray section 4 is disposed above the conveyance device 5 and sprays cleaning water (for example, pure water) downward for washing the work W. The spray section 4 has a tube for passage of the cleaning water and a plurality of spraying holes in communication with the tube. The tube of the spray section 4 for example has substantially the same length as the conveyance rollers 1 and is arranged substantially parallel to the roller shafts 11. The spraying holes are provided at locations in a lower face of the tube and are in a showerhead-like arrangement. The spray section 4 sprays downward the cleaning water supplied from a pump, not shown.

The washing device 100 having the above-described configuration washes the work W (a glass substrate) sent onto the conveyance rollers 1 by spraying the cleaning water from the spray section 4 while conveying the work W in a conveyance direction through rotation of the conveyance rollers 1. Each conveyance roller 1 has a longer length than a length of the work W in a direction orthogonal to the conveyance direction of the work W and supports the work W on a line. The surface of each conveyance roller 1 is formed from an elastic material (silicone rubber according to the present embodiment), and has a larger area of contact with the work W than that of a conventional conveyance device that supports the work W using conveyance rolls. Accordingly, the conveyance rollers 1 provide enhanced grip of the work W. Furthermore, each conveyance roller 1 has the enlarged portion 10a at the lower end thereof, and the conveyance roller 1 is axially supported such that a portion of the outer circumferential surface of the enlarged portion 10a is substantially horizontal. Thus, the work W can be kept from shifting downward from a proper position and prevented from sliding down. As described above, the conveyance device 5 of the washing device 100 according to Embodiment 1 is capable of stably conveying the work W. Since the conveyance rollers 1 in the above-described configuration can sufficiently convey the work W in a stable manner, the conveyance rollers 1 do not need collar portions such as those provided at the lower ends of the conveyance rollers used in the conventional conveyance device. Thus, the work W can be prevented from being damaged due to friction with such collar portions, and a glass break can be prevented from occurring due to the presence of the collar portions (for example, a glass break as a result of the work W coming down into a space between adjacent collar portions).

### Embodiment 2

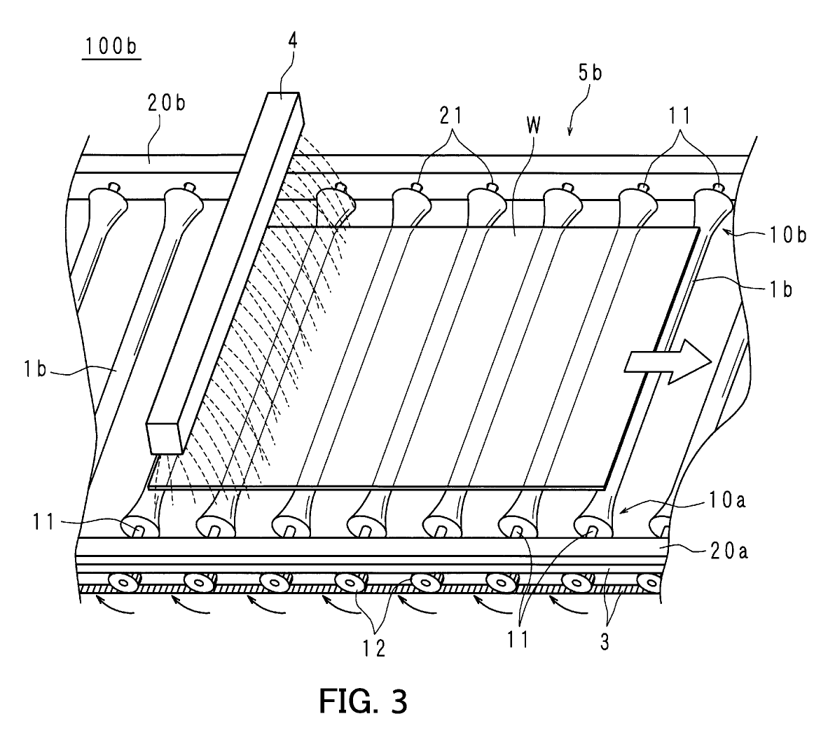

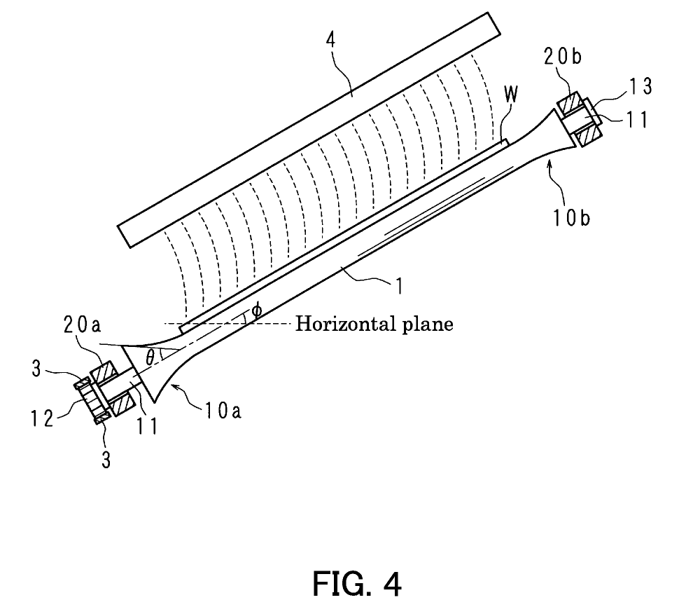

FIG. 3 is a perspective view schematically illustrating a washing device 100b according to Embodiment 2. FIG. 4 is a longitudinal cross-sectional view schematically illustrating the washing device 100b. Elements of configuration of the washing device 100b according to Embodiment 2 that are shared with the washing device according to Embodiment 1 are labelled using the same reference signs, and detailed description thereof is omitted.

The washing device 100b includes conveyance rollers 1b, pulleys 12, two frames 20 (a first frame 20a and a second frame 20b), a timing belt 3, and a spray section 4.

Like the conveyance rollers 1 according to Embodiment 1, each of the conveyance rollers 1b according to Embodiment 2 has a roller shaft 11 as a rotating shaft thereof. Other than the roller shaft 11, the conveyance roller 1b is formed from an elastic material such as silicone rubber. In addition to an enlarged portion 10a, each conveyance roller 1b further has an enlarged portion 10b at an opposite end thereof, which in other words is an upper end, toward the second frame 20b, and the enlarged portion 10b has a diameter gradually increasing toward the opposite end. For example, a greatest dimension of the enlarged portion 10b is smaller than or equal to a greatest dimension of the enlarged portion 10a. As in the case of the enlarged portion 10a, an outer circumferential surface of the enlarged portion 10b is a curved surface such that, for example, the outline of a longitudinal cross-section of the enlarged portion 10b is a curved line.

As in the case of Embodiment 1, the surface of each conveyance roller 1b of the washing device 100b according to Embodiment 2 is formed from an elastic material, and provides a larger area of contact between the conveyance roller 1b and a work W than that of a conventional conveyance device including conveyance rolls. Accordingly, the conveyance rollers 1b provide enhanced grip of the work W. Furthermore, the enlarged portions 10a can keep the work W from shifting downward from a proper position along the conveyance rollers 1. According to the present embodiment, each conveyance roller 1b has enlarged portions 10 (the enlarged portion 10a and the enlarged portion 10b) at the respective ends thereof. A distance of conveyance by the enlarged portions 10 at the respective ends and a distance of conveyance by a central portion, which is a portion other than the enlarged portions 10, in one rotation of the conveyance roller 1b are different. Specifically, the distance of conveyance by the enlarged portions 10 is greater. Accordingly, the enlarged portions 10a act to push up the work W and the enlarged portions 10b act to push down the work W having been pushed up. It is therefore possible to prevent the work W from skewing and thus stably convey the work W being tilted.

According to Embodiments 1 and 2, the work W that has reached the enlarged portions 10a of the conveyance rollers 1 or 1b is supported on curved lines of the conveyance rollers 1 or 1b. Preferably, the curvature of the outer circumferential surfaces of the enlarged portions 10a and the enlarged portions 10b is within an allowable range of flexure of the work W. Thus, the work W can be prevented from being damaged.

Note that the presently disclosed embodiments are merely examples in all aspects and should not be construed to be limiting. The scope of the present invention is indicated by the claims, rather than by the description given above, and includes all variations that are equivalent in meaning and scope to the claims.

### REFERENCE SIGNS LIST

W Work (glass substrate)

1, 1b Conveyance roller

10a, 10b Enlarged portion

20a, 20b Frame

1. A conveyance device comprising:
a first frame;
a second frame disposed at a higher location than the first frame and arranged substantially parallel to the first frame; and
a plurality of conveyance rollers axially supported on the first frame and the second frame, the conveyance rollers each having a surface formed from an elastic material and an enlarged portion at one end thereof toward the first frame, the enlarged portion having a diameter gradually increasing toward the one end.

2. The conveyance device according to claim 1, wherein
each of the conveyance rollers is axially supported at an angle relative to a horizontal plane, the angle being smaller than or equal to a largest inclination angle in the enlarged portion relative to an axial direction.

3. The conveyance device according to claim 1, wherein
each of the conveyance rollers further has an opposite enlarged portion at an opposite end thereof toward the second frame, the opposite enlarged portion having a diameter gradually increasing toward the opposite end.

4. A washing device comprising:
the conveyance device according to claim 1; and
a spray section disposed above the conveyance device and configured to spray cleaning water downward.

5. The conveyance device according to claim 1, wherein
the enlarged portion has an outer circumferential surface, and
an axial cross-section of the outer circumferential surface has a shape of a curved line.
